(19) United States
(12) Patent Application Publication
(10) Pub. No.: US 2025/0208494 A1
(43) Pub. Date: Jun. 26, 2025

(54) PROJECTION IMAGE DISPLAY DEVICE

(71) Applicant: Panasonic Holdings Corporation, Osaka (JP)

(72) Inventors: Shigekazu Yamagishi, Osaka (JP); Shigeyoshi Matsui, Osaka (JP)

(21) Appl. No.: 19/076,421

(22) Filed: Mar. 11, 2025

Related U.S. Application Data
(63) Continuation of application No. PCT/JP2023/033025, filed on Sep. 11, 2023.

(30) Foreign Application Priority Data
Sep. 12, 2022 (JP) 2022-144382

(51) Int. Cl. G03B 21/16; H05K 7/20

(52) U.S. Cl. CPC G03B 21/16; H05K 7/20145; H05K 7/20154

(57) ABSTRACT

A projection image display device according to the present disclosure includes a light source and an image display element on which light from the light source is incident, a first housing that houses the light source and the image display element and forms a sealed first space, a second housing that houses the first housing, forms a second space therebetween, and includes an intake port and an exhaust port for outside air, a first heat exchanger disposed in the second space that transfers heat of the image display element to outside air in the second space, a second heat exchanger disposed in the second space that transfers heat of the light source to outside air in the second space, and a first blower disposed in the second space, that takes outside air into the second space through the intake port, and discharges it through the exhaust port.

### CROSS REFERENCE TO RELATED APPLICATIONS

The present application is a continuation of PCT/JP2023/033025 filed on Sep. 11, 2023, which claims priority to Japanese Patent Application No. 2022-144382, filed on Sep. 12, 2022, the entire contents of each of which are incorporated herein by reference.

### TECHNICAL FIELD

The present disclosure relates to a projection image display device.

### BACKGROUND

A projection image display device irradiates an image display element such as liquid crystal with strong illumination light, and enlarges and projects an image displayed on the image display element with a projection lens. At this time, since the image display element absorbs a part of light, the image display element generates heat. In addition, since the projection light has large energy, the light source also generates heat. Therefore, effective heat removal from the image display element and the light source is required.

In general, outside air is taken into a projection image display device so as to cool a heat-generating component. However, when the outside air is taken in, dust and waste flow into the inside of the projection image display device together with the outside air. There is concern that the dust and waste may adhere to an optical system to deteriorate image quality, or may absorb light to cause heat generation.

In order to suppress inflow of the dust and refuse, a dustproof filter is provided at an inlet of outside air. In such a configuration, maintenance such as periodic replacement or cleaning of the dustproof filter is required.

In view of such a problem, for example, a projection image display device of WO 2019/225679 A has been proposed.

WO 2019/225679 A discloses a projection image display device including a plurality of blowers that cool a liquid crystal panel mounted on an illumination optical system, a heat sink that removes heat from air blown out from the blowers, and a dustproof case. The dustproof case houses the illumination optical system, the blower, and the heat sink, and has a sealed structure.

### SUMMARY

However, the sealed structure in WO 2019/225679 A does not include a light source. Therefore, a projection image display device cannot be used in an environment in which water is applied or an environment in which salt damage is concerned.

In view of solving the above-mentioned problem, an object of the present disclosure is to provide a projection image display device that cools heat-generating components in a sealed state.

An aspect of the present disclosure provides a projection image display device including a light source and an image display element on which light from the light source is incident, the projection image display device includes: a first housing that houses the light source and the image display element and forms a sealed first space; a second housing that houses the first housing, forms a second space between the first housing, and includes an intake port for outside air and an exhaust port for outside air; a first heat exchanger that is disposed in the second space and transfers heat of the image display element to outside air in the second space; a second heat exchanger that is disposed in the second space and transfers heat of the light source to outside air in the second space; and a first blower that is disposed in the second space, takes outside air into the second space through the intake port, and discharges the outside air in the second space through the exhaust port.

According to the present disclosure, it is possible to provide a projection image display device that cools heat-generating components in a sealed state.

### BRIEF DESCRIPTION OF DRAWINGS

FIG. 1 is a conceptual plan view of an overall configuration of a projection image display device according to a first embodiment;

FIG. 2 is a conceptual side view of an overall configuration of the projection image display device;

FIG. 3 is a schematic view illustrating a flow of air in the projection image display device;

FIG. 4 is a schematic perspective view illustrating an arrangement configuration of the projection image display device;

FIG. 5A is a front cross-sectional view in FIG. 4;

FIG. 5B is a cross-sectional view in which a cross-sectional position is changed from FIG. 5A in parallel direction;

FIG. 6 is a top cross-sectional view in FIG. 4;

FIG. 7A is a perspective view of a first heat exchanger;

FIG. 7B is a perspective view of a partition wall housed in the first heat exchanger;

FIG. 8 is a view illustrating an optical configuration;

FIG. 9 is a view illustrating an optical configuration of the projection image display device according to a second embodiment;

FIG. 10 is a top cross-sectional view of the projection image display device according to the second embodiment;

FIG. 11 is a cross-sectional view in which a cross-sectional position is changed from FIG. 10 in a vertical direction;

FIG. 12 is a cross-sectional view of an intake part of the projection image display device according to the second embodiment; and

FIG. 13 is a lower surface cross-sectional view of the projection image display device according to the second embodiment.

### DETAILED DESCRIPTION

Hereinafter, embodiments will be described in detail with reference to the drawings as appropriate. However, unnecessarily detailed description may be omitted. For example, a detailed description of a well-known matter and a repeated description of substantially the same configuration may be omitted. This is to avoid unnecessary redundancy of the following description and to facilitate understanding of those skilled in the art.

Note that, the accompanying drawings and the following description are provided for those skilled in the art to fully understand the present disclosure, and are not intended to limit the subject matter described in the claims. In addition, in each drawing, each element is exaggerated in order to facilitate the description.

### First Embodiment

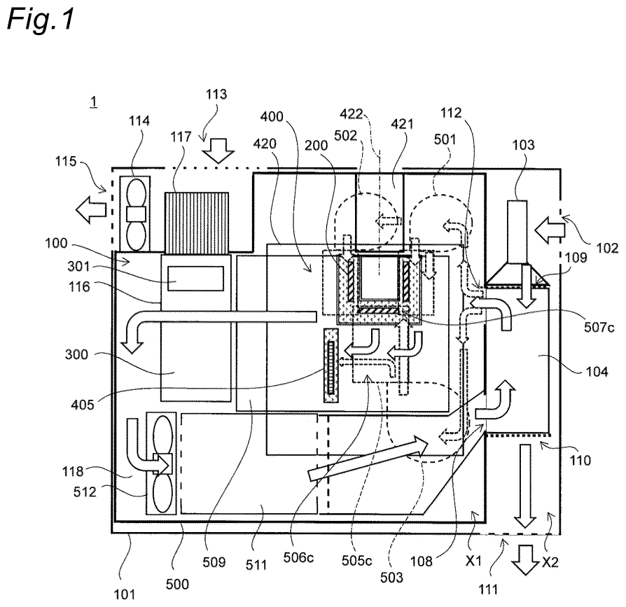

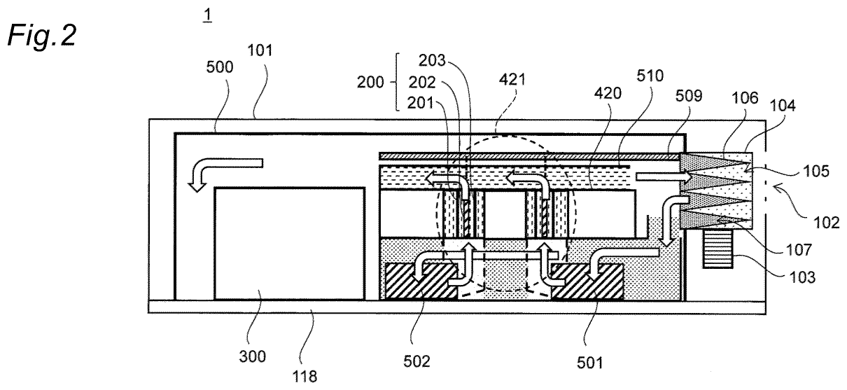

FIG. 1 is a conceptual plan view of an overall configuration of a projection image display device 1 according to a first embodiment. FIG. 2 is a conceptual side view of an overall configuration of the projection image display device 1. Essentially, each of the RGB optical paths should be described, but in FIG. 2, only two liquid crystal devices 200 are referred to due to the relationship of the drawings, and the illustration of the configuration related to a circulation fan 503 is omitted.

As illustrated in FIG. 1, the projection image display device 1 includes an optical configuration 100, a first housing 500, a second housing 101, a base 118, a first heat exchanger 104, a second heat exchanger 117, outside air fans 103 and 114, circulation fans 501 to 503, a power supply 511, and a power supply fan 512.

The optical configuration 100 includes a plurality of optical systems, and includes a light source 300 and an illumination optics 400 including a liquid crystal device 200. In the optical configuration 100, light from the light source 300 is guided to the illumination optics 400, and an image or a video displayed on the liquid crystal device 200 is enlarged and projected on a screen (not illustrated) by a projection lens 421. In a first embodiment, the light source 300 includes a laser light source 301, and the illumination optics 400 includes three liquid crystal devices 200 as an example of the image display element. The liquid crystal device 200 has a configuration in which a liquid crystal panel that displays an image to be enlarged and projected is sandwiched between two polarizing plates. When the image is enlarged and projected, the laser light source 301 and the liquid crystal device 200 generate heat. In order to remove the heat of the laser light source 301 and the liquid crystal device 200, cooling of the laser light source 301 and the liquid crystal device 200 is required.

The light source 300 is housed in a light source block 116, and the illumination optics 400 is housed in an illumination case 420. The light source block 116 may be formed of a heat insulating member.

The first housing 500 houses the laser light source 301 and the liquid crystal device 200, and forms sealed first space X1. In the first space X1, entry of outside air is restricted. In the first embodiment, the sealed first space X1 is airtight space in which inflow and outflow of external gas are blocked. The first space X1 only needs to be sealed with respect to the outside air, and may communicate with another sealed space.

In the first embodiment, the first housing 500 houses the optical configuration 100 including the laser light source 301 and the liquid crystal device 200 in the first space X1. By accommodating the optical configuration 100 in the first space X1, it is possible to suppress adhesion of dust and water droplets contained in outside air to the optical configuration 100 and to suppress occurrence of salt damage. The air in the first space X1 and other sealed spaces communicating with the first space X1 is referred to as inside air, and the air outside the first space X1 and other sealed spaces communicating with the first space X1 is referred to as outside air. The inside air is not limited to air, and may be helium or argon.

Although not illustrated in FIG. 1, the first housing 500 has a transparent glass plate on the emission surface side of the projection lens 421. With such a configuration, the projection lens 421 is sealed in the first space X1.

The second housing 101 is a member that houses the first housing 500. The second housing 101 forms a second space X2 between itself and the first housing 500. The second space X2 is divided into two spaces on one side and the other side of the first housing 500. The two spaces may communicate. Specifically, the second space X2 is divided into a space for accommodating the first heat exchanger 104 on one side of the first housing 500 and a space for accommodating the second heat exchanger 117 on the other side of the first housing 500.

Here, the first housing 500 being housed in the second housing 101 means that the first housing 500 is provided inside the outer peripheral surface of the second housing 101. In other words, the first housing 500 and the second housing 101 mainly form a double housing. On the other hand, the first housing 500 may have a portion common to the second housing 101 in a part thereof.

The second housing 101 includes intake ports 102 and 113 for outside air and exhaust ports 111 and 115 for outside air. In the second space X2, two paths are formed: a path through which the outside air flows into the second space X2 through the intake port 102 and flows out from the exhaust port 111; and a path through which the outside air flows into the second space X2 through the intake port 113 and flows out from the exhaust port 115.

By making the first housing 500 and the second housing 101 separate members, the first housing 500 and the second housing 101 can be formed of different materials. The first housing 500 may be formed of a material having a heat insulating property so as to suppress the thermal influence on the inside air from the outside. In addition, since the first housing 500 has a complicated shape so as to arrange and house a plurality of components in a compact manner, the first housing 500 may be formed of a moldable material. On the other hand, the second housing 101 may be formed of a material having weather resistance against external loads such as rain and wind and solar radiation. In the first embodiment, the first housing 500 is made of resin, and is, for example, a resin molded article such as engineering plastic. The second housing 101 is made of metal such as aluminum.

The base 118 is a plate-shaped member that supports the first housing 500 and the second housing 101. In other words, the base 118 constitutes a common bottom portion between the first housing 500 and the second housing 101. The base 118 may also support the optical configuration 100.

The first heat exchanger 104 is disposed in the second space X2, and transfers heat of the liquid crystal device 200 to the outside air in the second space X2. In other words, the first heat exchanger 104 performs heat exchange in one direction for cooling the liquid crystal device 200. As illustrated in FIG. 2, in the first embodiment, the first heat exchanger 104 has a partition wall 106 that defines an inside air flow path 107 on one surface and defines an outside air flow path 105 on the other surface. The outside air flow path 105 is in contact with the inside air flow path 107 via the partition wall 106. The inside air flow path 107 is a sealed flow path communicating with the first space X1. The inside air flow path 107 causes the inside air in the first space X1 to pass through the inside air flow path 107, and the outside air flow path 105 causes the outside air in the second space X2 to pass through the outside air flow path 105. The inside air flow path 107 includes an inlet 108 (FIG. 1) and an outlet 112 (FIG. 1) communicating with the first space X1. The inlet 108 causes inside air to pass from the first space X1 to the inside air flow path 107, and the outlet 112 causes inside air to pass from the inside air flow path 107 toward the first space X1.

The inside air in the first space X1 takes heat from the liquid crystal device 200 and increases air temperature. The heat of the liquid crystal device 200 is transferred from the inside air to the outside air through the partition wall 106 by the passage of the inside air and the outside air in the first heat exchanger 104. With such a configuration, cooling of the liquid crystal device 200 can be realized through the inside air.

Returning to FIG. 1, the first heat exchanger 104 is disposed between the intake port 102 and the exhaust port 111 in the second space X2. The outside air flowing from the intake port 102 to the exhaust port 111 passes through the outside air flow path 105 (FIG. 2).

The second heat exchanger 117 is disposed in the second space X2, and transfers the heat of the laser light source 301 to the outside air in the second space X2. In other words, the second heat exchanger 117 performs heat exchange in one direction to cool the laser light source 301. In the first embodiment, the second heat exchanger 117 is a heat sink connected to the laser light source 301. The second heat exchanger 117 penetrates the first housing 500 and is disposed between the intake port 113 and the exhaust port 115 in the second space X2. A seal is provided between the second heat exchanger 117 and the first housing 500, so that leakage of air from the first space X1 can be suppressed. The outside air flowing from the intake port 113 to the exhaust port 115 passes through the second heat exchanger 117. In addition, the laser light source 301 is directly or indirectly connected to the second heat exchanger 117 to carry heat from the laser light source 301. In the first embodiment, the second heat exchanger 117 is mechanically connected to the laser light source 301 via a thermally conductive material (grease or the like) on the back surface of the laser light source 301. The carried heat is dissipated toward the passing outside air. With such a configuration, cooling of the laser light source 301 can be realized.

The first heat exchanger 104 is disposed closer to the intake port 102 than the intake port 113, and the second heat exchanger 117 is disposed closer to the intake port 113 than the intake port 102. In the second housing 101, by providing the two intake ports 102 and 113 to divide the flow of outside air, the flow of the outside air in the first heat exchanger 104 and the flow of the outside air in the second heat exchanger 117 can be made independent from each other. With such a configuration, it is possible to cool the laser light source 301 without affecting the inside air in the first heat exchanger 104 and the first space X1 while avoiding imposing heat dissipation of the laser light source 301 on the first heat exchanger 104.

The outside air fan 103 is disposed in the second space X2, takes outside air into the second space X2 through the intake port 102, and discharges the outside air in the second space X2 through the exhaust port 111. The outside air fan 103 guides the outside air in the second space X2 to the outside air flow path 105 of the first heat exchanger 104, causes the outside air to pass through the outside air flow path 105, and discharges the outside air through the exhaust port 111.

The outside air fan 114 is a blower that is disposed in the second space X2, takes in outside air into the second space X2 through the intake port 113, and discharges the outside air from the exhaust port 115. The outside air fan 114 guides the outside air to the second heat exchanger 117.

The outside air fans 103 and 114 may be fans having weather resistance such as waterproofness or oil-proofness currently provided on the market because of direct exposure to the outside air. For example, the outside air fans 103 and 114 are axial fans or sirocco fans having waterproofness or oil-proofness.

The plurality of circulation fans 501 to 503 are blowers that are disposed in the first space X1, guide the inside air in the first space X1 to the inside air flow path 107, causes the inside air to pass through the inside air flow path 107, and guide the inside air to the liquid crystal device 200. In the first embodiment, the circulation fans 501 to 503 circulate inside air between the liquid crystal device 200 and the first heat exchanger 104. Specifically, the circulation fans 501 to 503 send, to the first heat exchanger 104, the inside air that has taken heat from the liquid crystal device 200 and has increased air temperature, and send again, to the liquid crystal device 200, the inside air that has been cooled in the first heat exchanger 104. With such a configuration, heat of the liquid crystal device 200 is carried to the first heat exchanger 104 through circulation of inside air. In the first embodiment, three circulation fans 501 to 503 corresponding to three liquid crystal devices 200, respectively are provided.

As illustrated in FIG. 2, the circulation fans 501 and 502 are disposed below the illumination case 420 accommodating the liquid crystal device 200. In addition, each optical system 201 to 203 of the liquid crystal device 200 is disposed such that the incident surface that receives the illumination light extends in the vertical direction. With respect to the liquid crystal device 200 disposed as described above, the circulation fans 501 and 502 suck in the inside air from the lateral direction and blows the inside air from the lower side to the upper side of the liquid crystal device 200. With such a configuration, it is possible to uniformly bring the inside air into contact with the incident surface of each optical system 201 to 203 of the liquid crystal device 200 to cool the optical systems 201 to 203.

In the first embodiment, as the circulation fans 501 to 503, a sirocco fan capable of obtaining a high static pressure in a limited space is employed.

Returning to FIG. 1, the power supply 511 is a member that supplies power to the light source 300 and an electric board 509. The electric board 509 is a board on which an electronic circuit that is electrically connected to the power supply 511 and controls the projection image display device 1 is mounted. The electronic circuit includes a circuit pattern formed on the electric board 509 and an electronic component electrically connected to the circuit pattern. The electric board 509 is disposed above the illumination case 420. The power supply 511 generates heat when energized. In order to suppress malfunctions, cooling of the power supply 511 is required.

The power supply fan 512 is a blower disposed near the power supply 511 in the first space X1. The power supply fan 512 blows inside air toward the power supply 511. With such a configuration, the power supply 511 can be cooled.

Next, a configuration related to cooling of the liquid crystal device 200 by the first heat exchanger 104 will be described in more detail.

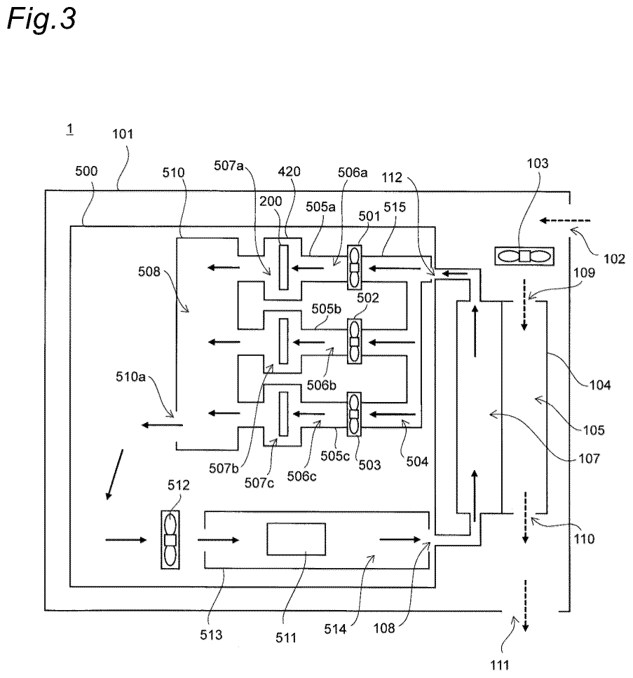

In order to cool the liquid crystal device 200, the first heat exchanger 104 causes inside air and outside air to pass therethrough to transfer heat from the inside air to the outside air. Therefore, first, flows of inside air and outside air in the projection image display device 1 will be described with reference to FIG. 3. FIG. 3 is a schematic view illustrating a flow of air in the projection image display device.

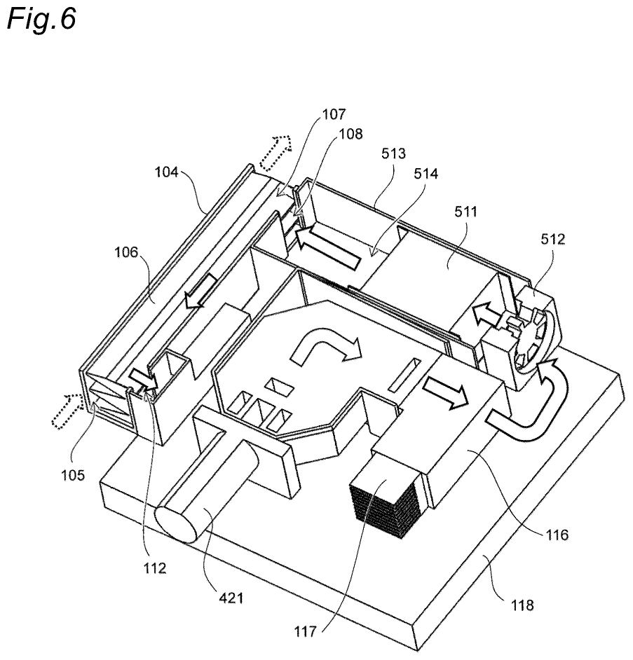

As illustrated in FIG. 3, when the outside air fan 103 rotates, the outside air flows into the second housing 101 through the intake port 102 and passes through the outside air flow path 105 (FIG. 6) of the first heat exchanger 104. The outside air that has flowed out of the outside air flow path 105 is discharged from the exhaust port 111 to the outside of the second housing 101.

On the other hand, the inside air circulates between the inside air flow path 107 of the first heat exchanger 104 and the first space X1. The inside air flow path 107 is connected to the first space X1 of the first housing 500 so as to form sealed space. The projection image display device 1 includes a plurality of air guiding ducts 515, 505a to 505c, the illumination case 420, an air guiding case 510, and a power supply air guiding duct 513 in the first space X1 so as to form a circulation path of inside air.

When the circulation fans 501 to 503 rotate, the inside air is sucked by the circulation fans 501 to 503, flows out from the outlet 112 of the inside air flow path 107, and flows into the air guiding duct 515. The inside air is sucked by each of circulation fans 501 to 503 and flows in each direction of the circulation fans 501 to 503 in a divided manner. The inside air sucked by the circulation fans 501 to 503 flows into the illumination case 420 in which the liquid crystal device 200 is disposed through air guiding ducts 505a to 505c. The inside air guided to the liquid crystal device 200 is discharged from the illumination case 420 and flows into the air guiding case 510.

When the power supply fan 512 rotates, the inside air is sucked by the power supply fan 512 and flows into the power supply air guiding duct 513 from a case outlet 510a. The inside air flows into the inside air flow path 107 of the first heat exchanger 104 through the inlet 108 via the power supply 511. The inside air flowing through the inside air flow path 107 returns to the outlet 112. With such a structure, the inside air circulates in the first housing 500.

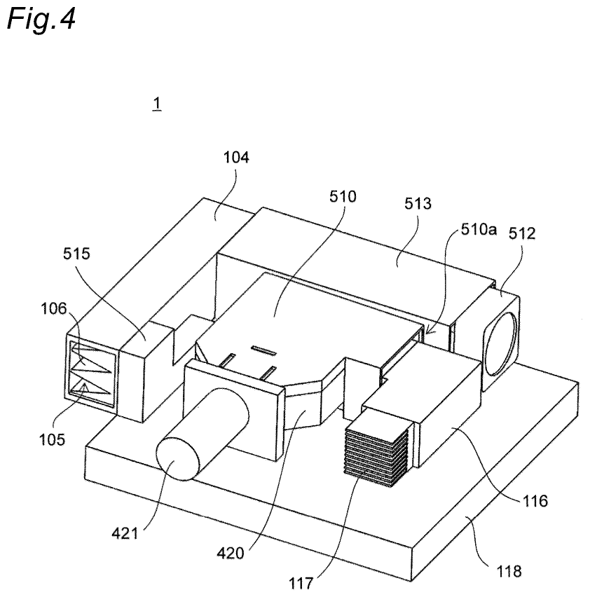

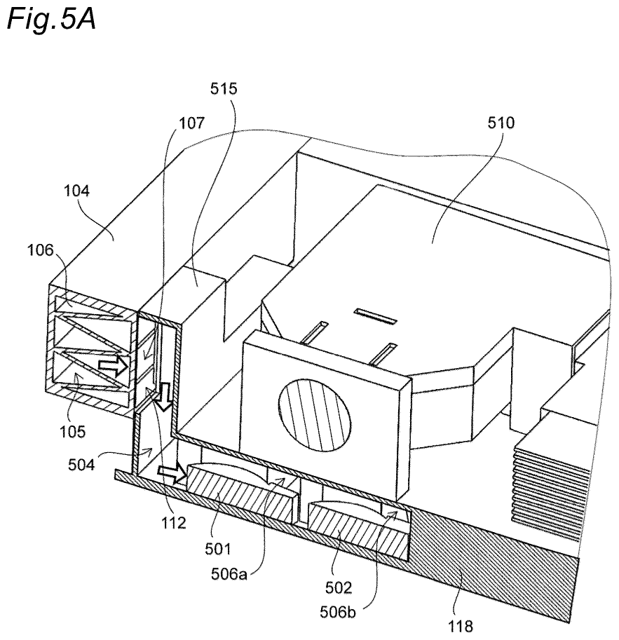

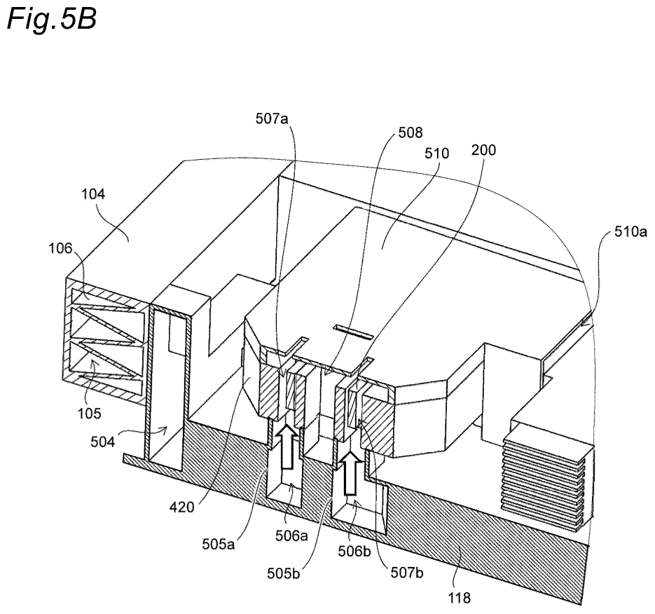

Next, the configuration related to the flow of inside air will be described more specifically with reference to FIGS. 4 to 6. FIG. 4 is a schematic perspective view illustrating an arrangement configuration of the projection image display device 1. In FIG. 4, the first housing 500 and the second housing 101 are omitted. FIG. 5A is a front cross-sectional view in FIG. 4. FIG. 5B is a perspective view in which a cross-sectional position is changed in parallel from FIG. 5A. FIG. 6 is a top cross-sectional view in FIG. 4.

As illustrated in FIGS. 4 and 5A, the air guiding duct 515 is a member that extends between the outlet 112 of the inside air flow path 107 of the first heat exchanger 104 and the circulation fans 501 to 503, and has a flow path therein. In the first embodiment, one end of the air guiding duct 515 is connected to the outlet 112 of the inside air flow path of the first heat exchanger 104, and the other ends of the air guiding duct 515 is connected to the intake ports of the circulation fans 501 to 503. A part of the air guiding duct 515 is formed by hollowing out a part of the base 118, but is not limited thereto.

A first flow path 504 is formed by the air guiding duct 515.

As illustrated in FIGS. 5A and 5B, the air guiding ducts 505a and 505b are members extending between circulation fans 501 and 502 and the liquid crystal device 200 and having flow paths therein. In the first embodiment, one end of each of the air guiding ducts 505a and 505b is connected to the discharge port of each of the circulation fans 501 and 502, and the other end of each of the air guiding ducts 505a and 505b is connected to the illumination case 420. The air guiding ducts 505a and 505b are formed by hollowing out a part of the base 118, but are not limited thereto.

Second flow paths 506a and 506b are formed by the air guiding ducts 505a and 505b, respectively.

Although not illustrated, the air guiding ducts 505a and 505b may have a nozzle shape at a connection portion with the illumination case 420. With such a structure, inside air is efficiently concentrated on the constituent member of the liquid crystal device 200.

As illustrated in FIG. 5B, the inner wall of the illumination case 420 defines third flow paths 507a and 507b communicating with the second flow paths 506a and 506b. The liquid crystal device 200 is housed in each of the third flow paths 507a and 507b. The third flow paths 507a and 507b extend in the longitudinal direction along the incident surface of the liquid crystal device 200.

In addition, although description of a circulation fan 503 is omitted in relation to the drawings, the air guiding duct 505c, a second flow path 506c, and a third flow path 507c are provided in the same manner as other circulation fans 501 and 502 (see FIG. 3).

As illustrated in FIGS. 4 and 5B, the air guiding case 510 is further provided on the illumination case 420. The inner wall of the air guiding case 510 forms a fourth flow path 508 with the upper surface of the illumination case 420. The air guiding case 510 forms the case outlet 510a at a position close to the power supply air guiding duct 513.

Returning to FIG. 2, the air guiding case 510 is disposed between the illumination case 420 and the electric board 509. By providing the air guiding case 510, it is possible to suppress contact of the inside air heated by taking heat from the liquid crystal device 200 with the electric board 509.

As illustrated in FIG. 6, the power supply air guiding duct 513 is a member that extends between the liquid crystal device 200 and the inlet 108 of the inside air flow path 107 of the first heat exchanger 104 and has a flow path therein. The power supply 511 is housed in the power supply air guiding duct 513. In the first embodiment, one end of the power supply air guiding duct 513 faces the power supply fan 512, and the other end of power supply air guiding duct 513 is connected to the inlet 108 of the inside air flow path of the first heat exchanger 104. The power supply fan 512 causes air to flow into the power supply air guiding duct 513.

A fifth flow path 514 is formed by the power supply air guiding duct 513.

With such a configuration, it is possible to more reliably blow inside air to the liquid crystal device 200 and the power supply 511 that generate heat, and blow the inside air heated there to the first heat exchanger 104.

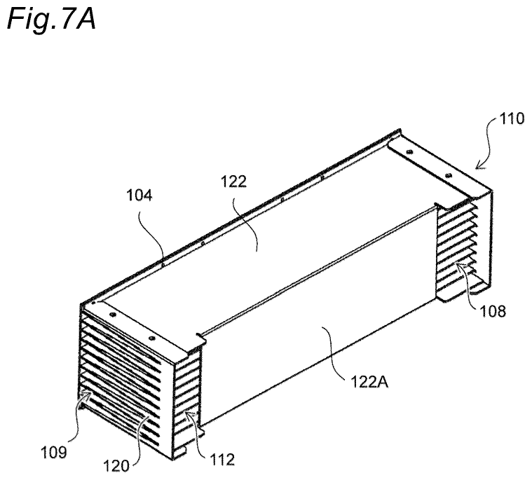

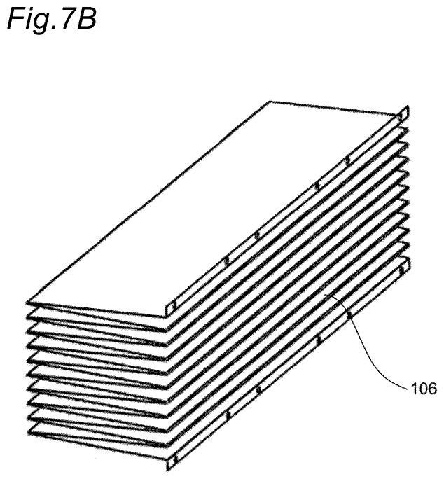

Next, the structure of the first heat exchanger 104 will be described in more detail with reference to FIGS. 7A and 7B. FIG. 7A is a perspective view of the heat exchanger 104. FIG. 7B is a perspective view of the partition wall 106 housed in the heat exchanger 104.

As illustrated in FIG. 7A, the first heat exchanger 104 includes a heat exchange case 122 and the partition wall 106 housed in the heat exchange case 122. In the first embodiment, the heat exchange case 122 has a rectangular parallelepiped shape. The partition wall 106 extends along the longitudinal direction of the heat exchange case 122 and divides the internal space of the heat exchange case 122 into two independent flow paths extending along the longitudinal direction. As illustrated in FIG. 7B, the partition wall 106 has a corrugated plate shape. Therefore, the area of the partition wall 106 in contact with the outside air and the inside air can be increased.

Returning to FIG. 7A, both ends in the longitudinal direction of the heat exchanger 104 are opened to the outside air on one side of the partition wall 106, and sealed by a comb-teeth shaped plate 120 on the other side of the partition wall 106. With such a structure, the outside air flow path 105 is opened to the outside air, and the inside air flow path 107 is sealed to the outside air.

One end of the opened heat exchanger 104 serves as an inlet 109 of the outside air flow path 105, and the other end serves as an outlet 110 of the outside air flow path 105. The inlet 109 of the outside air flow path 105 communicates with the intake port 102 (FIG. 1) of the second housing 101, and the outlet 110 of the outside air flow path 105 communicates with the exhaust port 111 (FIG. 1) of the second housing 101.

The inlet 108 and the outlet 112 of the inside air flow path 107 are formed on a side surface 122A connected to the first housing 500. Therefore, the inflow or outflow direction of the inside air intersects with the direction in which the inside air flow path 107 extends. In the first embodiment, the inflow or outflow direction of the inside air is orthogonal to the direction in which the inside air flow path 107 extends. In addition, the inlet 108 and the outlet 112 are disposed on substantially the same plane. With such a structure, it is possible to downsize the projection image display device 1 while securing the length of the inside air flow path 107. Since the flow velocity in the inside air flow path 107 is not fast, even if the inside air flow path 107 is bent, the inside air flows without any problem along with the pressure difference generated in each of the circulation fans 501 to 503.

The first heat exchanger 104 is connected to the side surface of the first housing 500 on the side surface 122A of the heat exchange case 122. The first heat exchanger 104 is connected so as to seal the first housing 500 so that no air leaks from the inside air flow path 107.

As illustrated in FIG. 1, the outlet 112 of the inside air flow path 107 is disposed closer to the liquid crystal device 200 than the inlet 108. In the first embodiment, the first heat exchanger 104 is disposed along the side surface of the first housing 500 such that the outlet 112 is located near the center of the liquid crystal device 200. Such an arrangement enables an arrangement that suppresses a difference in distance between the outlet 112 and each of the circulation fans 501 to 503. Therefore, the temperature bias of each cooling target (liquid crystal devices 200) can be suppressed.

Next, returning to FIGS. 3, 5A, 5B, and 6, heat transfer in the first heat exchanger 104 will be described.

As illustrated in FIG. 5A, when circulation fans 501 to 503 rotate, inside air flows out from the outlet 112 of the inside air flow path 107 and flows into the first flow path 504 formed by the air guiding duct 515.

As illustrated in FIG. 5B, the inside air sucked by the circulation fans 501 to 503 flows through the second flow paths 506a to 506c formed by the air guiding ducts 505a to 505c, into the third flow paths 507a to 507c in which the liquid crystal device 200 is disposed. In the third flow paths 507a to 507c, the inside air takes heat from the liquid crystal device 200 to increases air temperature.

As illustrated in FIGS. 5B and 6, the inside air is discharged toward the upper surface of the illumination case 420 and flows into the fourth flow path 508 formed by the air guiding case 510. When the power supply fan 512 rotates, the inside air flows out of the fourth flow path 508 through the case outlet 510a and passes through the upper surface of the light source block 116. Since the light source block 116 is cooled by another path, the temperature rise of the inside air by the light source block 116 is suppressed.

As illustrated in FIG. 6, the inside air flowing out of the case outlet 510a flows into the fifth flow path 514 formed by the power supply air guiding duct 513. In the fifth flow path 514, the inside air takes heat from the power supply 511 to increase air temperature. In addition, the power supply 511 is disposed downstream of the liquid crystal device 200 as viewed in the flow direction of the inside air. With such a configuration, it is possible to bring the inside air before the increase in air temperature into contact with the liquid crystal device 200 having a low target temperature to improve the cooling effect in the liquid crystal device 200.

Thereafter, the inside air flows into the inside air flow path 107 through the inlet 108 in a state where the inside air is heated by taking heat from the liquid crystal device 200 and the power supply 511. When combined with the flow of outside air in the outside air flow path 105, the inside air passes through the inside air flow path 107, exchanges heat with the outside air passing through the outside air flow path 105, and is cooled in the first heat exchanger 104. In other words, heat is transferred from the inside air to the outside air through the partition wall 106. The direction in which inside air flows in the inside air flow path 107 (solid arrow) and the direction in which outside air flows in the outside air flow path 105 (dotted arrow) are opposite to each other. Therefore, heat can be efficiently transferred from the inside air to the outside air.

Due to the heat transfer, the temperature of the inside air at the outlet 112 is lower than the temperature of the inside air at the inlet 108. Therefore, the inside air is returned into the first housing 500 at a temperature lower than that in the state of flowing into the first heat exchanger 104.

By repeating the circulation of the inside air, the inside air and each component in the first housing 500 can be maintained at desired temperatures without directly taking in the outside air.

Next, heat transfer in the second heat exchanger 117 will be described.

As illustrated in FIG. 1, when the outside air fan 114 rotates, the outside air flows into the second housing 101 through the intake port 113 and collides with the second heat exchanger 117. The outside air having collided with the second heat exchanger 117 and increased in temperature is discharged from the exhaust port 115 to the outside of the second housing 101. Since the path of the outside air with respect to the second heat exchanger 117 is separated from the first heat exchanger 104, the laser light source 301 generating large amounts of heat can be efficiently cooled, and the cooling of the laser light source 301 can be suppressed from affecting the cooling of other members and the inside air. For example, the amount of heat generated by the laser light source 301 is half of the input power.

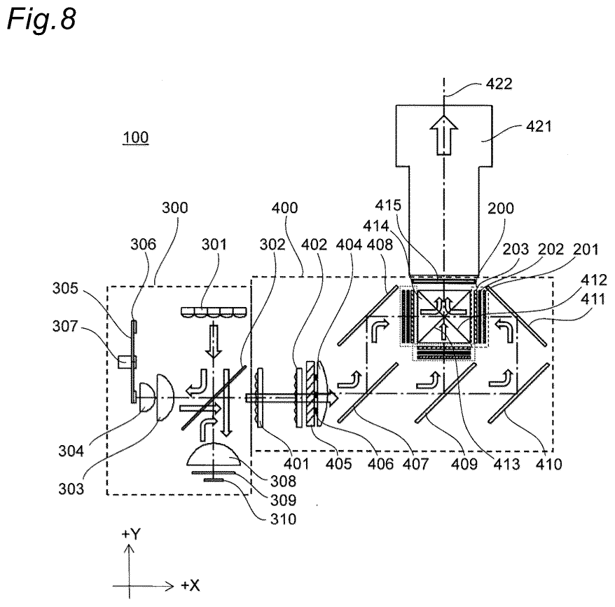

A detailed configuration of the optical configuration 100 will be described with reference to FIG. 8. FIG. 8 is a view illustrating the optical configuration 100 of the projection image display device 1 according to the first embodiment. The optical configuration 100 includes the light source 300 and the illumination optics 400.

### [1. Configuration of Light Source]

The light source 300 includes the laser light source 301, a dichroic mirror 302, excitation lenses 303 and 304, a reflection disk 305, a condenser lens 308, a circularly polarizing plate 309, and a diffusion reflection mirror 310.

The laser light source 301 emits blue light, and includes a plurality of lasers arranged in an array and a collimating lens in front of each laser.

The dichroic mirror 302 is disposed obliquely, reflects only S-polarized light of incident light, and transmits only P-polarized light (light that is not S-polarized light).

The excitation lenses 303 and 304 condense the passing light in a point shape.

A phosphor 306 is applied to the reflection disk 305 in an annular shape, and the phosphor 306 fluoresces yellow light using blue light as excitation light. The reflection disk 305 is rotated by a motor 307. The phosphor 306 locally generates heat by being irradiated with light, but an excessive temperature rise is suppressed by rotation.

The circularly polarizing plate 309 makes the incident light circularly polarized light.

The diffusion reflection mirror 310 reflects the incident light as diffused light.

The blue light from the laser light source 301 is emitted in the −Y direction and is incident on the dichroic mirror 302. The S-polarized component of the blue light is reflected in a −X direction. The P-polarized component of the blue light is transmitted in a −Y direction.

The S-polarized component reflected by the dichroic mirror 302 is incident on the phosphor 306 on the reflection disk 305 by the excitation lenses 303 and 304. When incident on the phosphor 306, the incident light becomes yellow light, and returns to the dichroic mirror 302 again in a state where the light beam width is enlarged by the excitation lenses 303 and 304. Since the yellow light is transmitted through the dichroic mirror 302, the yellow light is incident on the illumination optics 400.

On the other hand, the P-polarized component transmitted through the dichroic mirror 302 is incident on and focused on the diffusion reflection mirror 310 as the circularly polarized light by the condenser lens 308 and the circularly polarizing plate 309. The diffused light reflected from the diffusion reflection mirror 310 travels in a +Y direction with the rotation direction of the circularly polarized light reversed, and is incident on the circularly polarizing plate 309 again. When the diffused light is incident with the rotation direction of the circularly polarized light reversed, the light becomes S-polarized blue light and is incident on the dichroic mirror 302 when transmitted through the circularly polarizing plate 309. Since the S-polarized blue light is reflected by the dichroic mirror 302, the blue light is reflected and is incident on the illumination optics 400.

With such a configuration, yellow light and blue light are incident on the illumination optics 400 from the light source 300.

### [2. Configuration of Illumination Optics]

The illumination optics 400 includes fly-eye lenses 401 and 402, a condenser lens 404, a PBS 405, mirrors 407 to 411, the liquid crystal device 200, a cross-color prism 414, and the projection lens 421. The illumination optics 400 includes three liquid crystal devices 200 for each color light (RGB). The illumination optics 400 may be referred to as a projection optical system.

The fly-eye lenses 401 and 402 includes a large number of rectangular microlenses having the same shape. Each microlens on the emission side of the fly-eye lens 402 corresponds to any microlens on the incident side fly-eye lens 401. The light passes through the fly-eye lenses 401 and 402 to form a rectangular illumination area on the front side (+X direction) by each microlens on the emission side fly-eye lens 402.

The condenser lens 404 condenses light received from the fly-eye lenses 401 and 402, and rectangular area images are superimposed to form a uniform illumination area.

The PBS 405 is an aggregate of quadrangular prisms having a parallelogram cross section, and is formed by applying a polarization selective film to an oblique surface and sticking a strip-shaped retardation plate 406 to an emission surface. Since the function of the PBS 405 is not essential to the establishment of the present disclosure, the description here will be reserved to state that the incident light is emitted as the color light in which the polarization directions are aligned. In the configuration of the PBS 405, since the strip-shaped retardation plate 406 is an organic material, appropriate temperature control is required.

The mirrors 407 to 411 are mirrors for deflecting light received from the condenser lens 404 to the liquid crystal device 200. Specifically, the mirrors 407 and 409 are dichroic mirrors, and the mirrors 408, 410, and 411 are reflective mirrors.

The liquid crystal device 200 includes an incident side polarizing plate 201, a liquid crystal panel 202, and an emission side polarizing plate 203 which are arranged in order from the incident side of each color light. A rectangular range formed by the fly-eye lenses 401 and 402 and the condenser lens 404 is set so as to cover the image display range of the liquid crystal panel 202.

The incident side polarizing plate 201 is formed by bonding a polarizing plate to base glass. The polarization axis of the polarizing plate is set so as to transmit only light in the polarization direction of light incident on the rectangular range. The polarizing plate in the incident side polarizing plate 201 absorbs several percent of the light even when the polarizing axes of the transmitted light are aligned, thus, generates heat.

The liquid crystal panel 202 includes liquid crystal independently controllable for each of a large number of pixels. A light shielding mask for preventing malfunctions of the driving electric components is provided between the pixels. For example, the light incident on the liquid crystal panel 202 is transmitted in the polarization direction at the time of incidence or receives an action to change the polarization direction by the liquid crystal drive circuit that has received the video signal for each pixel of the liquid crystal, and passes through the liquid crystal panel 202. In the liquid crystal panel 202, light is absorbed by a light shielding mask or slightly by the liquid crystal, so that the liquid crystal panel 202 generates heat.

The emission side polarizing plate 203 is formed by bonding a polarization selective member (polarizing plate or wire grid) to base glass. For example, the polarized light not driven by the liquid crystal panel 202 is almost transmitted with only slight absorption by the polarization selective member on the emission side polarizing plate 203, but the polarized light driven by the liquid crystal panel 202 is absorbed according to the degree of modulation and is not transmitted. Therefore, the emission side polarizing plate 203 generates heat. Since the emission side polarizing plate 203 generates larger heat than other members particularly at the time of black display, a plurality of aluminum wire grids having excellent heat resistance or polarizing plates having a low degree of polarization may be used in combination as the polarization selective member.

Since the liquid crystal device 200 generates heat, it is required to cool the liquid crystal device 200 so as to maintain the driving performance of the liquid crystal or to suppress the deterioration of the polarizing plate.

The cross-color prism 414 includes a red reflection dichroic coating 412 and a blue reflection dichroic coating 413. Each color light is composed by the cross-color prism 414.

The projection lens 421 is set to be capable of enlarging and projecting an image formed on the liquid crystal panel 202 of the liquid crystal device 200 onto a screen not illustrated in the drawing.

Here, the light incident from the light source 300 passes through the incident side fly-eye lens 401 and the emission side fly-eye lens 402, and a rectangular illumination area is formed on the front side (+X direction) by each microlens on the emission side fly-eye lens 402. These illumination areas are condensed by the condenser lens 404, and rectangular area images are superimposed to form a uniform illumination area. As described above, the light guided to the rectangular range formed by the fly-eye lenses 401 and 402 and the condenser lens 404 is aligned in an arbitrary polarization direction.

The light that has passed through the condenser lens 404 is incident on a dichroic mirror 407. The dichroic mirror 407 has a characteristic of reflecting only blue light and transmitting other color light. The blue light reflected by the dichroic mirror 407 is further reflected by a reflection mirror 408 and reaches the blue member of the liquid crystal device 200. The yellow light transmitted through the dichroic mirror 407 is incident on a dichroic mirror 409 having a characteristic of reflecting the green light, so that only the green light component reaches the green member of the liquid crystal device 200. The red light remaining as the transmission obtained by removing the green component from the yellow by the dichroic mirror 409 is reflected by reflection mirrors 410 and 411 and reaches the red member of the liquid crystal device 200.

Each color light transmitted through the liquid crystal device 200 is synthesized in the +Y direction by the cross-color prism 414 and emitted, transmitted through a dust-proof glass 415, and reaching the projection lens 421. When the light is emitted from the projection lens 421, the image displayed by the liquid crystal device 200 is enlarged and projected on the screen.

### (Effects)

According to the projection image display device 1 according to the present embodiment, the following effects can be obtained.

As described above, the projection image display device 1 according to the present embodiment is a projection image display device including the laser light source 301 (light source) and the liquid crystal device 200 (image display element) on which light from the laser light source 301 is incident. The projection image display device 1 includes the first housing 500, the second housing 101, the first heat exchanger 104, the second heat exchanger 117, and the outside air fan 103 (first blower). The first housing 500 houses the laser light source 301 and the liquid crystal device 200, and forms the sealed first space X1. The second housing 101 houses the first housing 500, forms the second space X2 between the first housing 500, and includes the intake port 102 for outside air and the exhaust port 111 for outside air. The first heat exchanger 104 is disposed in the second space X2, and transfers heat of the liquid crystal device 200 to the outside air in the second space X2. The second heat exchanger 117 is disposed in the second space X2, and transfers the heat of the laser light source 301 to the outside air in the second space X2. The outside air fan 103 is disposed in the second space X2, takes outside air into the second space X2 through the intake port 102, and discharges the outside air in the second space X2 through the exhaust port 111.

With such a configuration, the laser light source 301 and the liquid crystal device 200 that generate heat can be cooled in a sealed state. Therefore, it is possible to suppress adhesion of dust and water droplets contained in outside air to the laser light source 301 and the liquid crystal device 200 and occurrence of salt damage. In addition, the heat of the laser light source 301 and the liquid crystal device 200 is transferred to outside air through different heat exchangers 104 and 117, so that cooling can more efficiently be realized.

In the projection image display device 1 according to the present embodiment, the first heat exchanger 104 includes the partition wall 106 that defines the inside air flow path 107 with a surface on one side and defines the outside air flow path 105 with a surface on the other side. The inside air flow path 107 includes the inlet 108 and the outlet 112 communicating with the first space X1. The outside air flow path 105 is in contact with the inside air flow path 107 via the partition wall 106 and allows outside air to pass through the outside air flow path 106. The projection image display device 1 further includes the circulation fans 501 to 503 (second blowers) that are disposed in the first space X1, guides the inside air in the first space X1 to the inside air flow path 107, causes the inside air to pass through the inside air flow path 107, and guides the inside air to the liquid crystal device 200. The outside air fan 103 guides the outside air in the second space X2 to the outside air flow path 105, causes the outside air to pass through the outside air flow path 105, and discharges the outside air through the exhaust port 111.

With such a configuration, in the first heat exchanger 104, the heat generated in the liquid crystal device 200 can be transferred from inside air to outside air. In addition, the cooled inside air can be blown to the liquid crystal device 200 to cool the liquid crystal device 200.

The projection image display device 1 according to the present embodiment further includes the air guiding duct 515 (first duct) and the air guiding ducts 505a to 505c (second duct). The air guiding duct 515 extends between the outlet 112 of the inside air flow path 107 of the first heat exchanger 104 and the circulation fans 501 to 503. The air guiding ducts 505a to 505c extend between the circulation fans 501 to 503 and the liquid crystal device 200.

With such a configuration, the cooled inside air can be blown to the liquid crystal device 200 more reliably.

The projection image display device 1 according to the present embodiment further includes the power supply air guiding duct 513 (third duct) extending between the liquid crystal device 200 and the inlet 108 of the inside air flow path 107 of the first heat exchanger 104. The power supply 511 of the laser light source 301 is housed in the power supply air guiding duct 513.

With such a configuration, it is possible to blow the inside air to the power supply 511 to cool the power supply 511. In addition, by blowing the inside air to the liquid crystal device 200 before blowing the inside air to the power supply 511, it is possible to obtain a greater cooling effect in the liquid crystal device 200. Therefore, even when the liquid crystal device 200 has a low target temperature, the heat generation of the liquid crystal device 200 can be maintained at the target temperature or less.

The projection image display device 1 according to the present embodiment further includes the power supply fan 512 (third blower) that causes air to flow into the power supply air guiding duct 513.

With such a configuration, it is possible to blow inside air to the power supply 511 more reliably.

In the projection image display device 1 according to the present embodiment, the first flow path 504 is formed by the air guiding duct 515. The second flow paths 506a to 506c are formed by the air guiding ducts 505a to 505c. The fifth flow path 514 (third flow path) is formed by the power supply air guiding duct 513. The third flow paths 507a to 507c (fourth flow paths) that house the liquid crystal device 200 and communicate with the second flow paths 506a to 506c are formed.

With such a configuration, it is possible to blow inside air to the liquid crystal device 200 more reliably.

In the projection image display device 1 according to the present embodiment, the second heat exchanger 117 is the heat sink connected to the laser light source 301.

With such a configuration, the heat of the laser light source 301 is transferred to the heat sink in the second space X2 through heat conduction, and is dissipated to outside air.

In the projection image display device 1 according to the present embodiment, the second housing 101 includes the intake port 102 (first intake port) and the intake port 113 (second intake port) as intake ports. The first heat exchanger 104 is disposed closer to the intake port 102 than the intake port 113. The second heat exchanger 117 is disposed closer to the intake port 113 than the intake port 102.

With such a configuration, it is possible to bring outside air having a relatively low temperature before heat exchange into contact with each of the heat exchangers 104 and 117. That is, the laser light source 301 and the liquid crystal device 200 are cooled by paths of outside air that are different from each other. Therefore, the liquid crystal device 200 can be efficiently cooled by the first heat exchanger 104 while avoiding imposing the cooling of the laser light source 301 on the first heat exchanger 104.

The projection image display device 1 according to the present embodiment further includes the outside air fan 114 (fourth blower) that is disposed in the second space X2, takes outside air into the second space X2 through the intake port 113, and guides the outside air to the second heat exchanger 117.

With such a configuration, it is possible to improve the heat dissipation effect in the second heat exchanger 117.

In the projection image display device 1 according to the present embodiment, the partition wall 106 has a corrugated shape.

With such a configuration, by increasing contact area between the outside air flow path 105 and the inside air flow path 107, it is possible to improve the heat exchange efficiency in the first heat exchanger 104.

In the projection image display device 1 according to the present embodiment, the outside air fan 103 is an axial fan or the sirocco fan having waterproofness or oil-proofness.

With such a configuration, it is possible to suppress a failure of the outside air fan 103 and to obtain a high static pressure while saving space.

In the projection image display device 1 according to the present embodiment, the first housing 500 and the second housing 101 have the common base 118 as a bottom portion.

Such a configuration facilitates manufacturing of the housings 500 and 101. In addition, it is easy to assemble the projection image display device 1, and the height of the entire device can also be suppressed.

In the projection image display device 1 according to the present embodiment, the first housing 500 is made of resin, and the second housing 101 is made of metal.

With such a configuration, the first housing 500 made of a material having a heat insulating property is less likely to be thermally affected by outside air. In addition, the first housing 500 having a complicated shape can be easily formed by resin molding. The second housing 101 made of metal has improved strength and weather resistance as compared to a case where the second housing 101 is made of resin.

In the projection image display device 1 according to the present embodiment, the first housing includes the liquid crystal device 200, and houses the projection optical system that projects modulated light.

With such a configuration, it is possible to suppress adhesion of dust and water droplets contained in outside air to the projection optical system and occurrence of salt damage. Therefore, the projection image display device 1 can be used outdoors or in an environment exposed to water.

In the projection image display device 1 according to the present embodiment, the direction in which inside air flows in the inside air flow path 107 and the direction in which outside air flows in the outside air flow path 105 are opposite to each other.

With such a configuration, heat exchange efficiency in the first heat exchanger 104 is improved.

In the first embodiment, it has been described that the sealed space is an airtight space in which inflow and outflow of gas to and from the outside are blocked, but the present disclosure is not limited thereto. The sealed space may be a liquid-tight space in which entry of dust or the like is suppressed and liquid such as water is prevented from entering from the outside.

In the first embodiment, an example in which three circulation fans 501 to 503 are provided has been described. However, the present disclosure is not limited thereto. The number and arrangement of the circulation fans may be appropriately changed according to the required air volume.

In the first embodiment, an example in which the power supply fan 512 is provided has been described, but the present disclosure is not limited thereto. The power supply fan 512 is not necessarily required as long as a required air volume is produced by the circulation fans 501 to 503.

In the first embodiment, an example in which the air guiding case 510 is provided has been described, but the present disclosure is not limited thereto. In a case where the space between the illumination case 420 and the electric board 509 is narrow, it is conceivable that the air guiding case 510 may hinder the flow of air, so the air guiding case 510 is not necessarily required.

In the first embodiment, an example in which the first heat exchanger 104 includes the partition wall 106 and the second heat exchanger 117 is a heat sink has been described, but the present disclosure is not limited thereto. The first heat exchanger 104 and the second heat exchanger 117 may have other configurations capable of exchanging heat. The first heat exchanger 104 may have a configuration including a general heat sink, a heat pipe, or partition walls having different configurations as long as the outside air and the inside air are separated and intake and discharge positions of the outside air and the inside air are established.

In the first embodiment, an example in which the second heat exchanger 117 is mechanically connected to the laser light source 301 has been described, but the present disclosure is not limited thereto. The second heat exchanger 117 may be connected to the laser light source 301 via a fluid such as a refrigerant. For example, the second heat exchanger 117 includes a heat transfer tube that circulates a refrigerant. Heat exchange between inside air and outside air around the laser light source 301 can be realized through circulation of the refrigerant. When the inside air around the laser light source 301 is cooled, the laser light source 301 is cooled.

Note that, in the first embodiment, an example in which the second housing 101 and the first housing 500 have the common base 118 has been described, but the present disclosure is not limited thereto. The first housing 500 may have a base inside the second housing 101. With such a configuration, the air layer is formed between the base of the second housing 101 and the base of the first housing 500, so that it is possible to suppress the temperature change of the inside air due to the thermal contact from the outside. On the other hand, when the base 118 is common, it is possible to reduce the number of members and to downsize the projection image display device 1.

The circulation fans 501 to 503 and the outside air fans 103 and 114 may be controlled according to the inside air temperature, the outside air temperature, and the altitude. With such a configuration, it is possible to minimize generated noise while suppressing the temperature to a desired value. The circulation fans 501 to 503 are disposed in the first space X1, and thus may be controlled only by a temperature monitor in the first housing 500.

Part of the inside air sucked by the circulation fan 503 may flow into a space surrounding the PBS 405. The inside air takes heat from the PBS 405 to increase air temperature. With such a configuration, the PBS 405 can be cooled by removing heat.

In the first embodiment, the configuration in which three transmissive liquid crystal panels are used in the liquid crystal device 200 has been described, but the present disclosure is not limited thereto. A reflective liquid crystal panel may be used.

### Second Embodiment

A projection image display device 150 according to a second embodiment of the present disclosure will be described. In the second embodiment, points different from the first embodiment will be mainly described. In the second embodiment, the same or equivalent configurations as those of the first embodiment will be described with the same reference numbers. In the second embodiment, the description overlapping with the first embodiment is omitted.

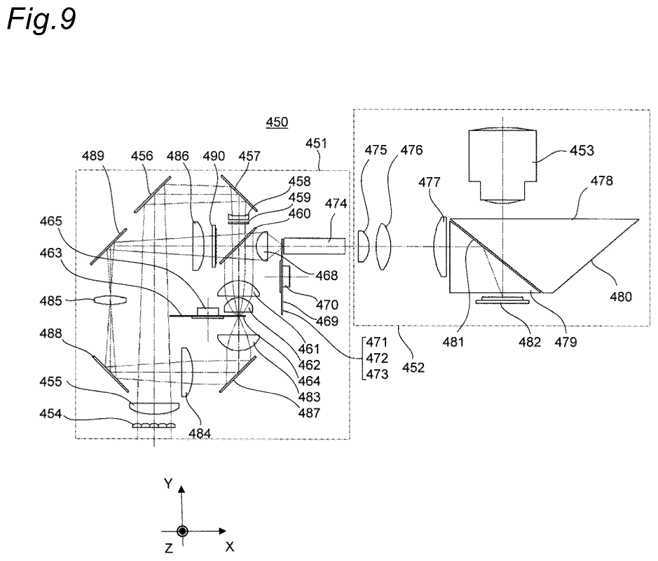

FIG. 9 is a view illustrating an optical configuration 450 of the projection image display device 150 according to the second embodiment. The right direction in the view is defined as a +X direction, the upper direction is defined as a +Y direction, and the direction toward the front is defined as a +Z direction.

As illustrated in FIG. 9, the projection image display device 150 according to the second embodiment is different from the projection image display device 1 according to the first embodiment in that a color display is performed using a digital mirror device (DMD) instead of the liquid crystal device 200. Unless described, the projection image display device 150 may have a structure similar to the projection image display device 1 of the first embodiment.

The projection image display device 150 includes an illumination optical system 451 and a projection optical system 452 including a projection lens 453.

The illumination optical system 451 includes a laser light source 454 as a light source. The laser light source 454 is a semiconductor laser that emits blue light similar to the laser light source 301 of the first embodiment, and emits the blue light forward (in the +Y direction). The emitted light is incident on a condenser lens 455 and is focused. The focused light is incident on a condenser lens 458 that is a concave lens via folding mirrors 456 and 457, is converted into parallel light with a reduced height from the laser light source 454, and is incident on a diffuser plate 459. The diffuser plate 459 increases uniformity of the light, and the light is incident on a dichroic mirror 460.

The dichroic mirror 460 has a characteristic of transmitting light having a blue wavelength and reflecting visible light having another wavelength. Therefore, as in the first embodiment, since the light transmitted through the diffuser plate 459 is the blue light, the blue light is transmitted and focused by excitation lenses 461 and 462. The focused light forms a focused spot on a phosphor applied on a phosphor wheel 464 of a phosphor device 463.

The phosphor wheel 464 is rotatably fixed to a motor 465, and includes a range including a yellow phosphor on a circumference on which a focused spot is formed, and a fan-shaped opening in a partial range on the same circumference. The phosphor receives intense excitation light and approximately half of the energy received is heat. When the temperature of the phosphor is equal to or higher than a certain temperature, the conversion efficiency decreases due to the temperature quenching characteristic, and the reliability decreases due to high heat generation.

The fluorescent light generated by the yellow phosphor in the phosphor wheel 464 returns to the dichroic mirror 460 via the excitation lenses 461 and 462 as diffused light. The dichroic mirror 460 reflects the incident yellow fluorescence. When the yellow fluorescence is incident on a condenser lens 468, the yellow fluorescence is incident on the color filter of a color wheel 469. The color wheel 469 can rotate the color filter at a high speed by a motor 470. The color filter includes a red transmission filter 471 that selectively transmits only light having a red wavelength, a green transmission filter 472 that selectively transmits only light having a green wavelength, and a transparent glass 473 obtained by applying antireflection treatment to transparent glass. Each of the red transmission filter 471, the green transmission filter 472, and the transparent glass 473 is formed in a fan shape, and is fixed to a motor hub to form a disk shape with the above three members. Note that, synchronization is performed such that light is incident on the red transmission filter 471 and the green transmission filter 472 at the timing when the yellow phosphor is irradiated with the excitation light. Light with a wavelength other than a wavelength required for the fluorescent light incident by the red transmission filter 471 and the green transmission filter 472 is removed, and a desired color purity is realized.

The light that has passed through the color filter reaches the incident surface of a rod integrator 474, repeats total reflection, and then reaches a TIR prism 478 of a projection optical system 452 via a projection system relay lenses 475 and 476 and a field lens 477.

In the TIR prism 478, an incident side prism 479 and an emission side prism 480 are bonded via an air gap of several microns. The light incident on the incident side prism 479 from the field lens 477 is totally reflected by an air gap surface 481, is emitted from the incident side prism 479, and is incident on a DMD 482 which is a light modulation element.

The DMD 482 is a device including a plurality of micromirrors provided in a matrix at two inclination angles selectable with respect to a base substrate. The inclination angle of the micromirror is changed on the basis of a video signal from the outside. For example, the micromirror is selectively inclined between a first inclination angle at which the reflected light is incident on the projection lens 453 and a second inclination angle at which the light emitted from the incident side prism 479 becomes a larger incident angle and the reflected light is reflected to a position where the reflected light does not enter the projection lens 453. The DMD 482 realizes the mirror switching operation at high speed according to the video signal corresponding to the color light that is temporally switched and incident as described above.

On the other hand, the light incident on the opening in the phosphor wheel 464 of the phosphor device 463 is transmitted without being affected by the phosphor device 463. The blue transmitted light is diffused by a diffuser plate 490 via a blue light relay optical path including relay lenses 483, 484, 485, and 486 and mirrors 487, 488, and 489. Thereafter, the light having the blue wavelength transmits through the dichroic mirror 460 that reflects only the yellow light to follow the same optical path as the other color light, and transmits through the transparent glass 473 of the color filter of the color wheel 469. The timing at which the light is transmitted through an opening 467 of a wheel substrate, the timing at which the light is transmitted through the transparent glass 473 of the color filter, and the timing at which the DMD 482 is driven by the video signal for blue are synchronized. Thereafter, the color image can be obtained on a screen (not illustrated) by the projection lens 453 after being modulated by the DMD 482 through an optical path similar to that of the red light and the green light.

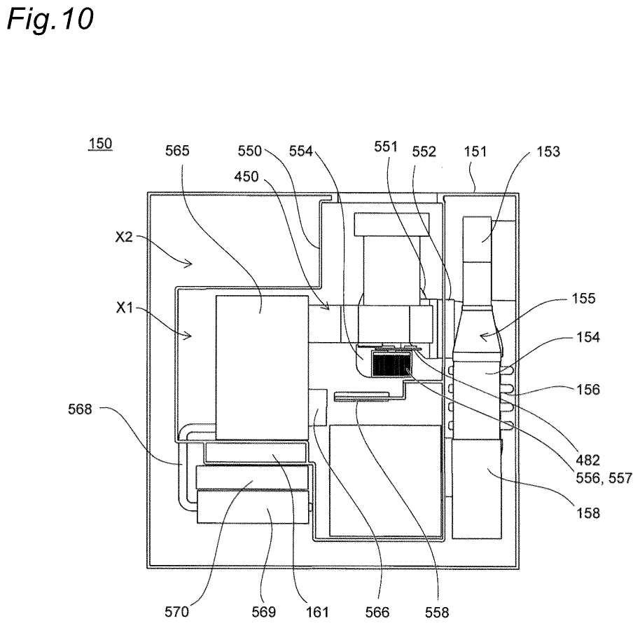

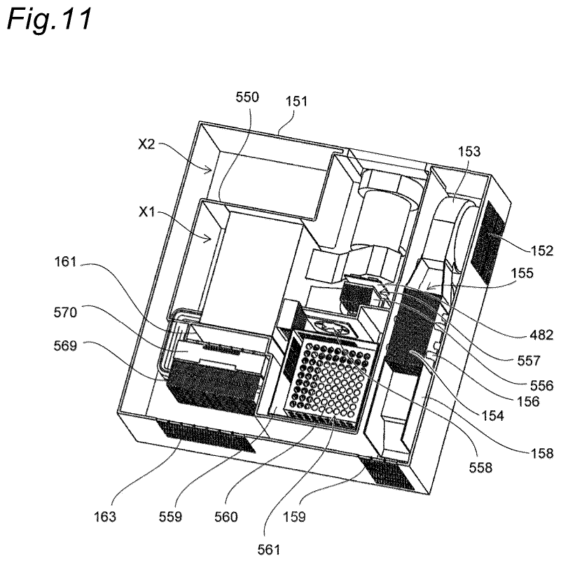

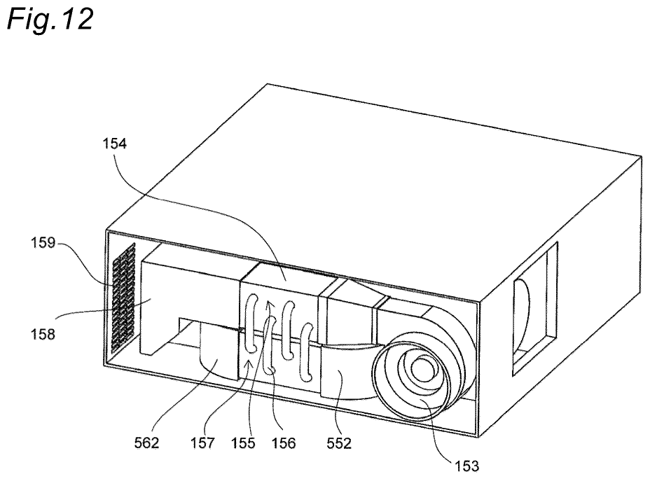

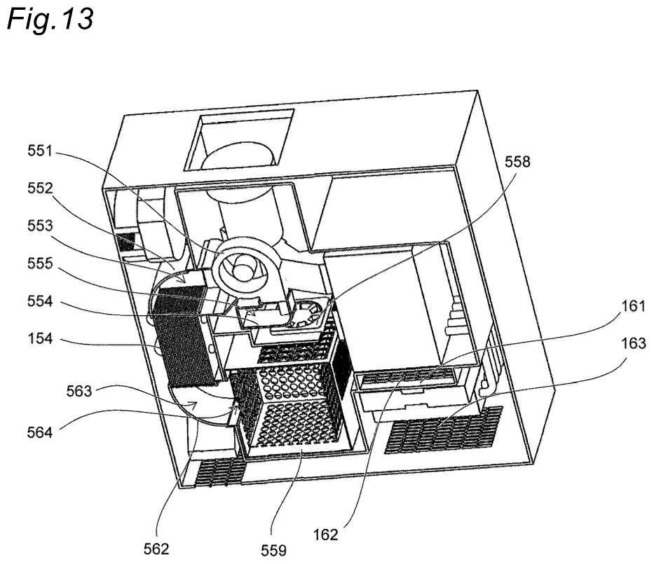

FIG. 10 is a top cross-sectional view of the projection image display device 150 according to the second embodiment. FIG. 11 is a top cross-sectional view in which the cross-sectional position is changed in the vertical direction from FIG. 10. FIG. 12 is a cross-sectional view of an intake part of the projection image display device 150 according to the second embodiment. FIG. 13 is a lower surface cross-sectional view of the projection image display device 150 according to the second embodiment.

As illustrated in FIGS. 10 and 11, the projection image display device 150 includes the optical configuration 450 described above, a first housing 550, a second housing 151, a first heat exchanger 154, an intake fan 153, a DMD heat sink 556, a circulation fan 551, a power supply 560, and a light source heat sink 566.

The first housing 550 and the second housing 151 have the similar configurations to those of the first embodiment, the first housing 550 forming a sealed first space X1, and a second space X2 communicating with the outside is formed between the first housing 550 and the second housing 151.

As illustrated in FIG. 11, the second housing 151 includes an intake port 152 and an exhaust port 159. An exhaust duct 158 is connected to the exhaust port 159.

As illustrated in FIGS. 11 and 12, the first heat exchanger 154 includes an outside air duct, fins, an inside air duct, and a first heat pipe 156. The outside air duct is connected to the intake fan 153 and the exhaust duct 158, and forms an outside air flow path 155 through which outside air flows. The fins are disposed in the outside air flow path 155 and extend along a direction in which the outside air flows. A plurality of fins are provided and arranged in parallel to each other. The fins are formed of, for example, aluminum. The inside air duct forms an inside air flow path 157 through which inside air flows. The inside air flow path 157 communicates with the first space X1. Similarly to the outside air flow path 155, the inside air flow path 157 is provided with the plurality of fins. The first heat pipe 156 is a general heat pipe in which a small amount of water is added to a vacuumed sealed tube to vaporize on the high temperature side and liquefy on the low temperature side to take the temperature on the high temperature side as heat of vaporization. The first heat pipe 156 is disposed so as to penetrate the plurality of fins in the inside air flow path 157 and the plurality of fins in the outside air flow path 155. With such a configuration, the inside air having passed through the inside air flow path 157 can exchange heat with the outside air through the fins without directly mixing with the outside air.

The intake fan 153 takes outside air into the second housing 151 through the intake port 152 and blows the outside air to the first heat exchanger 154. The outside air having passed through the first heat exchanger 154 is discharged to the outside via the exhaust duct 158 and the exhaust port 159 of the second housing 151. The intake fan 153 may be a member already supplied to the market as a waterproof fan or an oil-proof fan.

The DMD heat sink 556 is connected to a back surface of the DMD 482 via a heat conductive material (grease or the like). By drawing heat from the back surface, it is possible to secure reliability of the DMD 482.

The circulation fan 551 is a blower that is disposed in the first space X1 and circulates inside air between the first heat exchanger 154 and the sealed first space X1. As the circulation fan 551, the sirocco fan is adopted in order to obtain high static pressure in a limited space.

The power supply 560 includes the similar configuration to the power supply 511 of the first embodiment.

As illustrated in FIG. 10, the light source heat sink 566 is connected to a light source case 565 that houses the laser light source 454, the phosphor device 463, the color wheel 469, and peripheral optical components thereof in the illumination optical system 451. The light source heat sink 566 is disposed near a power supply fan 558. The light source heat sink 566 enhances heat dissipation of the light source case 565.

The light source heat sink 566 includes a heat receiving portion 567 (not illustrated). The heat receiving portion 567 is connected via a heat conductive material to the back surface of the laser light source 454 (FIG. 9) that generates a large amount of heat. One end of a heat pipe 568 is embedded in the heat receiving portion 567. The other end of the heat pipe 568 is connected to a heat dissipation fin 569, and a light source cooling fan 570 is provided adjacent to the heat dissipation fin 569. Therefore, the heat of the laser light source 454 reaches the heat dissipation fin 569 from the heat receiving portion 567 through the heat pipe 568. In other words, the heat receiving portion 567, the heat pipe 568, and the heat dissipation fin 569 together form a heat exchanger. The light source cooling fan 570 may be a member already supplied to the market as a waterproof fan or an oil-proof fan.

A vent hole 161 is formed on the intake side of the light source cooling fan 570. The vent hole 161 is formed in the second housing 151 and communicates with an intake port 162 (FIG. 13) including a large number of openings. Therefore, the heat dissipation fin 569 can efficiently dissipate heat with the outside air flowing from the intake port 162 and having a relatively lower temperature than the inside air. The heated outside air is exhausted from an exhaust port 163 (FIG. 11) formed in the second housing 151.

With such a configuration, the heat of the light source having a large heat dissipation amount can be processed separately from the first heat exchanger 154. This is particularly effective when the light source can be directly connected and absorb heat like a laser light source. In this case, since the light source can be directly cooled, space saving of a configuration related to heat exchange can be achieved. Specifically, as compared with a configuration using a conventional light source such as a discharge lamp that is required to perform heat exchange between air and air (gas) so as to lower the ambient temperature, space saving of a configuration related to heat exchange can be achieved.

Next, circulation of inside air in the first space X1 will be described.

As illustrated in FIG. 13, inside air is guided from the first heat exchanger 154 by the circulation fan 551 to a first flow path 553 formed by a first air guiding duct 552. The first flow path 553 is a sealed flow path between the first heat exchanger 154 and the circulation fan 551.

The inside air guided by the circulation fan 551 reaches a second flow path 555 formed by a second air guiding duct 554 connected to the discharge port of the circulation fan 551. The second flow path 555 is a sealed flow path between the circulation fan 551 and the DMD 482.

As illustrated in FIG. 11, the DMD heat sink 556 is housed in a third flow path 557 communicating with the second flow path 555. The second air guiding duct 554 (FIG. 13) may include an opening at a connection portion to the third flow path 557, and the connection portion may have a nozzle shape. With such a configuration, air is concentrated on the DMD heat sink 556. The inside air takes heat from the DMD heat sink 556.

The air that has passed through the third flow path 557 reaches a fourth flow path 561 formed by a third air guiding duct 559 and housing the power supply 560 via the power supply fan 558. The inside air takes heat from the power supply 560 to increase air temperature.

As illustrated in FIG. 13, the third air guiding duct 559 forms a partition wall opening 564 at least on the power supply fan 558 side and a fourth duct 562 side. The partition wall opening 564 is connected to a fifth flow path 563, and the fifth flow path 563 is connected to the inside air flow path 157 (FIG. 12). As a result, the heated inside air reaches the inside air flow path 157 of the first heat exchanger 154.

When the inside air flows around the plurality of fins in the inside air flow path 157, heat is exchanged with the outside air flow path 155, and heat is removed from the inside air. Therefore, the temperature of the inside air decreases, and the inside air circulates through the flow path leading to the first flow path 553 again in a relatively low temperature state.

As described above, it is clear that the present disclosure is also effective in a configuration in which the DMD is used as the image display element. The similar effect can be expected in the LED which is a solid light source.

In the second embodiment, the configuration in which one DMD is used has been described, but the present disclosure is not limited thereto. Any number of DMDs may be used.

In the second embodiment, the example in which the first heat exchanger 154 uses the heat pipe has been described, but the present disclosure is not limited thereto. The first heat exchanger 154 may have another configuration such as a configuration using a corrugated plate. Conversely, it is needless to say that a heat exchanger including a heat pipe and a fin can be used in the first embodiment.

In the second embodiment, the example in which the cooling air is concentrated on the DMD heat sink 556 on the back surface of the DMD 482 has been described, but the present disclosure is not limited thereto. The inside air from the circulation fan 551 may be branched toward the projection optical system or the DMD 482 for cooling. In addition, a dedicated circulation fan may be additionally installed.

In the second embodiment, the example in which the power supply fan 558 is provided has been described, but the present disclosure is not limited thereto. In a case where a sufficient flow rate of the inside air can be secured with respect to the light source heat sink 566 so that the temperature rise of the light source case 565 can be suppressed, the power supply fan 558 may be omitted.

A projection image display device of a first aspect includes a light source, an image display element on which light from the light source is incident, a first housing that houses the light source and the image display element and forms a sealed first space, a second housing that houses the first housing, forms a second space between the first housing, and includes an intake port for outside air and an exhaust port for outside air, a first heat exchanger that is disposed in the second space and transfers heat of the image display element to outside air in the second space, a second heat exchanger that is disposed in the second space and transfers heat of the light source to outside air in the second space, and a first blower that is disposed in the second space, takes outside air into the second space through the intake port, and discharges the outside air in the second space through the exhaust port.

The projection image display device of a second aspect, depending on the first aspect wherein the first heat exchanger includes a partition wall that defines an inside air flow path on a surface on one side and defines an outside air flow path on a surface on another side, the inside air flow path includes an inlet and an outlet communicating with the first space, and the outside air flow path is in contact with the inside air flow path via the partition wall and causes outside air to pass through the outside air flow path, the projection image display device further including a second blower that is disposed in the first space, guides inside air in the first space to the inside air flow path, causes the inside air to pass through the inside air flow path, and guides the inside air to the image display element, the first blower guiding outside air in the second space to the outside air flow path, causing the outside air to pass through the outside air flow path, and discharging the outside air through the exhaust port.

The projection image display device of a third aspect, depending on the second aspect wherein the projection image display device further includes a first duct extending between the outlet of the inside air flow path of the first heat exchanger and the second blower, and a second duct extending between the second blower and the image display element.

The projection image display device of a fourth aspect, depending on the third aspect wherein the projection image display device further includes a third duct extending between the image display element and the inlet of the inside air flow path of the first heat exchanger, wherein a power supply of the light source is housed in the third duct.

The projection image display device of a fifth aspect, depending on the fourth aspect wherein the projection image display device further includes a third blower that causes air to flow into the third duct.

The projection image display device of a sixth aspect, depending on the fourth or fifth aspect wherein a first flow path is formed by the first duct, a second flow path is formed by the second duct, a third flow path is formed by the third duct, and a fourth flow path that houses the image display element and communicates with the second flow path is formed.

The projection image display device of a seventh aspect, depending on the fourth or fifth aspect wherein a third heat exchanger is connected to the image display element, a first flow path is formed by the first duct, a second flow path is formed by the second duct, a third flow path is formed by the third duct, and a fourth flow path that houses the third heat exchanger and communicates with the second flow path is formed.

The projection image display device of an eighth aspect, depending on any one of the first to seventh aspects wherein the second heat exchanger is a heat sink connected to the light source.

The projection image display device of a ninth aspect, depending on any one of the first to eighth aspects wherein the second housing includes a first intake port and a second intake port as the intake ports, the first heat exchanger is disposed closer to the first intake port than the second intake port, and the second heat exchanger is disposed closer to the second intake port than the first intake port.

The projection image display device of a tenth aspect, depending on the ninth aspect wherein the projection image display device further includes a fourth blower that is disposed in the second space, takes outside air into the second space through the second intake port, and guides the outside air to the second heat exchanger.

The projection image display device of an eleventh aspect, depending on any one of the second to seventh aspects wherein the partition wall has a corrugated shape.

The projection image display device of a twelfth aspect, depending on any one of the first to eleventh aspects wherein the first blower is an axial fan or a sirocco fan having waterproofness or oil-proofness.

The projection image display device of a thirteenth aspect, depending on any one of the first to twelfth aspects wherein the first housing and the second housing have a common base as a bottom portion.

The projection image display device of a fourteenth aspect, depending on any one of the first to thirteenth aspects wherein the first housing is made of resin, and the second housing is made of metal.

The projection image display device of a fifteenth aspect, depending on any one of the first to fourteenth aspects wherein the first housing includes the image display element and houses a projection optical system that projects modulated light.

The projection image display device of a sixteenth aspect, depending on any one of the second to seventh aspects wherein a direction in which inside air flows in the inside air flow path and a direction in which outside air flows in the outside air flow path are opposite to each other.

Although the present disclosure has been fully described in connection with preferred embodiments with reference to the accompanying drawings, various variations and modifications will be apparent to those skilled in the art. Such variations and modifications are to be understood as being included within the scope of the present disclosure as set forth in the appended claims.

The present disclosure is applicable to a projection image display device and a projection video display device including a member that generates heat.

What is claimed is:

1. A projection image display device comprising:
a light source;
an image display element on which light from the light source is incident;
a first housing that houses the light source and the image display element and forms a sealed first space;
a second housing that houses the first housing, forms a second space between the first housing, and includes an intake port for outside air and an exhaust port for outside air;
a first heat exchanger that is disposed in the second space and transfers heat of the image display element to outside air in the second space;
a second heat exchanger that is disposed in the second space and transfers heat of the light source to outside air in the second space; and
a first blower that is disposed in the second space, takes outside air into the second space through the intake port, and discharges the outside air in the second space through the exhaust port.

2. The projection image display device according to claim 1, wherein
the first heat exchanger includes a partition wall that defines an inside air flow path on a surface on one side and defines an outside air flow path on a surface on another side,
the inside air flow path includes an inlet and an outlet communicating with the first space, and
the outside air flow path is in contact with the inside air flow path via the partition wall and causes outside air to pass through the outside air flow path,
the projection image display device further comprising a second blower that is disposed in the first space, guides inside air in the first space to the inside air flow path, causes the inside air to pass through the inside air flow path, and guides the inside air to the image display element,
the first blower guiding outside air in the second space to the outside air flow path, causing the outside air to pass through the outside air flow path, and discharging the outside air through the exhaust port.

3. The projection image display device according to claim 2, further comprising:
a first duct extending between the outlet of the inside air flow path of the first heat exchanger and the second blower; and
a second duct extending between the second blower and the image display element.

4. The projection image display device according to claim 3, further comprising a third duct extending between the image display element and the inlet of the inside air flow path of the first heat exchanger,
wherein a power supply of the light source is housed in the third duct.

5. The projection image display device according to claim 4, further comprising a third blower that causes air to flow into the third duct.

6. The projection image display device according to claim 4, wherein
a first flow path is formed by the first duct,
a second flow path is formed by the second duct,
a third flow path is formed by the third duct, and
a fourth flow path that houses the image display element and communicates with the second flow path is formed.

7. The projection image display device according to claim 4, wherein
a third heat exchanger is connected to the image display element,
a first flow path is formed by the first duct,
a second flow path is formed by the second duct,
a third flow path is formed by the third duct, and
a fourth flow path that houses the third heat exchanger and communicates with the second flow path is formed.

8. The projection image display device according to claim 1, wherein the second heat exchanger is a heat sink connected to the light source.

9. The projection image display device according to claim 1, wherein
the second housing includes a first intake port and a second intake port as the intake ports,
the first heat exchanger is disposed closer to the first intake port than the second intake port, and
the second heat exchanger is disposed closer to the second intake port than the first intake port.

10. The projection image display device according to claim 9, further comprising a fourth blower that is disposed in the second space, takes outside air into the second space through the second intake port, and guides the outside air to the second heat exchanger.

11. The projection image display device according to claim 2, wherein the partition wall has a corrugated shape.

12. The projection image display device according to claim 1, wherein the first blower is an axial fan or a sirocco fan having waterproofness or oil-proofness.

13. The projection image display device according to claim 1, wherein the first housing and the second housing have a common base as a bottom portion.

14. The projection image display device according to claim 1, wherein
the first housing is made of resin, and
the second housing is made of metal.

15. The projection image display device according to claim 1, wherein the first housing includes the image display element and houses a projection optical system that projects modulated light.

16. The projection image display device according to claim 2, wherein a direction in which inside air flows in the inside air flow path and a direction in which outside air flows in the outside air flow path are opposite to each other.
